(19) United States
(12) Patent Application Publication
(10) Pub. No.: US 2024/0313183 A1
(43) Pub. Date: Sep. 19, 2024

(54) DISPLAY MODULE AND MANUFACTURING METHOD THEREOF

(71) Applicant: SAMSUNG ELECTRONICS CO., LTD., Suwon-si (KR)

(72) Inventors: Yoonsuk LEE, Suwon-si (KR); Seungryong HAN, Suwon-si (KR)

(73) Assignee: SAMSUNG ELECTRONICS CO., LTD., Suwon-si (KR)

(21) Appl. No.: 18/663,886

(22) Filed: May 14, 2024

Related U.S. Application Data
(63) Continuation of application No. PCT/KR2024/002310, filed on Feb. 22, 2024.

(30) Foreign Application Priority Data
Mar. 2, 2023 (KR) 10-2023-0027840
May 4, 2023 (KR) 10-2023-0058310

(51) Int. Cl. H01L 33/62; H01L 25/075; H01L 33/00; H01L 33/42

(52) U.S. Cl. CPC H01L 33/62; H01L 25/0753; H01L 33/0093; H01L 33/42

(57) ABSTRACT

A display module is provided and includes an inorganic light emitting device; a first electrode at a first side of the inorganic light emitting device; a second electrode at a second side of the inorganic light emitting device, opposite to the first side; a first film layer including first conductive particles, the first film layer being between the first substrate and the inorganic light emitting device; and a second film layer including second conductive particles, the second film layer being between the second substrate and the inorganic light emitting device, wherein the first film layer is configured to connect the first electrode and the inorganic light emitting device through at least one of the first conductive particles, and wherein the second film layer is configured to connect the second electrode and the inorganic light emitting device through at least one of the second conductive particles.

### CROSS-REFERENCE TO RELATED APPLICATIONS

This application is a bypass continuation of International Application No. PCT/KR2024/002310, filed on Feb. 22, 2024, in the Korean Intellectual Property Receiving Office, which claims priority to Korean Patent Application No. 10-2023-0027840, filed on Mar. 2, 2023, and Korean Patent Application No. 10-2023-0058310, filed on May 4, 2023, in the Korean Intellectual Property Office, the disclosures of which are incorporated by reference herein in their entireties.

### BACKGROUND

### 1. Field

The disclosure relates to a display module and a manufacturing method thereof and, more particularly to, a display module with reduced manufacturing cost by simplifying a manufacturing process and a manufacturing method thereof.

### 2. Description of the Related Art

With the development of electronic technology, various types of electronic devices have been developed. Particularly, various types of display products using light emitting diodes (LEDs) have been developed recently.

However, manufacturing costs are increased due to use of miniaturized and highly-integrated light emitting diodes, and the difficulty of a manufacturing process is increased.

### SUMMARY

According to an aspect of the disclosure, a display module includes: an inorganic light emitting device including a lower electrode on a first side of the inorganic light emitting device and an upper electrode on a second side of the inorganic light emitting device, opposite to the first side; a first substrate at the first side of the inorganic light emitting device and including a first electrode; a second substrate at the second side of the inorganic light emitting device and including a second electrode; a first film layer between the first substrate and the inorganic light emitting device and including a plurality of first conductive particles; and a second film layer between the second substrate and the inorganic light emitting device and including a plurality of second conductive particles, wherein the first film layer is configured to connect the first electrode and the lower electrode through at least one of the plurality of first conductive particles, and wherein the second film layer is configured to connect the second electrode and the upper electrode through at least one of the plurality of second conductive particles.

At least one of the plurality of first conductive particles and the plurality of second conductive particles may be fine conductive particles, and at least one of the first film layer and the second film layer may include an anisotropic conductive film including the fine conductive particles.

The display module may further include an additional inorganic light emitting device that is adjacent to the inorganic light emitting device, and a distance between adjacent fine conductive particles among the fine conductive particles in the anisotropic conductive film may be less than a distance between the inorganic light emitting device and the additional inorganic light emitting device.

At least one of the plurality of first conductive particles and the plurality of second conductive particles may include elastic protrusions coated with a conductive material on a polymer ball, and at least one of the first film layer and the second film layer may include a non-conductive film including the elastic protrusions.

The display module may further include an additional inorganic light emitting device that is adjacent to the inorganic light emitting device, and a distance between adjacent elastic protrusions among the elastic protrusions in the non-conductive film may be less than a distance between the inorganic light emitting device and the additional inorganic light emitting device.

At least one of the first substrate and the second substrate may include a transparent material.

Each of the upper electrode, the lower electrode, the first electrode, and the second electrode may include a transparent material.

According to an aspect of the disclosure, a method of manufacturing a display module, includes: forming a first substrate including a first electrode at an upper portion of the first substrate; disposing at least one first conductive particle on an upper portion of the first electrode; bonding a first film layer to the upper portion of the first substrate; disposing an inorganic light emitting device on an upper portion of the first film layer, the inorganic light emitting device including an upper electrode and a lower electrode formed on opposite sides of the inorganic light emitting device; connecting the first substrate and the lower electrode through the at least one first conductive particle by bonding the first substrate and the inorganic light emitting device using at least one of heat and pressure; disposing a second substrate and a second film layer, bonded to a lower portion of the second substrate, on an upper portion of the inorganic light emitting device, the second substrate including a second electrode at the lower portion of the second substrate, and the second film layer including at least one second conductive particle under the second electrode; and connecting the upper electrode and the second electrode through the at least one second conductive particle by bonding the second substrate and the inorganic light emitting device using at least one of heat and pressure.

The disposing the second substrate and the second film layer may include: forming the second substrate; disposing the at least one second conductive particle at the lower portion of the second electrode; bonding the second film layer to the lower portion of the second substrate; and disposing the second substrate at the upper portion of the inorganic light emitting device.

The at least one first conductive particle and the at least one second conductive particle may be elastic protrusions coated with a conductive material on a polymer ball, and the first film layer and the second film layer may include a non-conductive film.

The method may further include disposing an additional inorganic light emitting device on the upper portion of the first film layer such as to be adjacent to the inorganic light emitting device, and a distance between adjacent elastic protrusions among the elastic protrusions in the non-conductive film may be less than distance between the inorganic light emitting device and the additional inorganic light emitting device.

At least one of the first substrate and the second substrate may include a transparent material.

Each of the upper electrode, the lower electrode, the first electrode, and the second electrode may include a transparent material.

According to an aspect of the disclosure, a display module includes: an inorganic light emitting device; a first electrode at a first side of the inorganic light emitting device; a second electrode at a second side of the inorganic light emitting device, opposite to the first side; a first film layer between the first electrode and the inorganic light emitting device and including a plurality of first conductive particles; and a second film layer being between the second electrode and the inorganic light emitting device and including a plurality of second conductive particles, wherein the first film layer may be configured to connect the first electrode and the inorganic light emitting device through at least one of the plurality of first conductive particles, and the second film layer may be configured to connect the second electrode and the inorganic light emitting device through at least one of the plurality of second conductive particles.

At least one of the plurality of first conductive particles and the plurality of second conductive particles may be fine conductive particles, and at least one of the first film layer and the second film layer may include an anisotropic conductive film including the fine conductive particles.

At least one of the plurality of first conductive particles and the plurality of second conductive particles may include elastic protrusions coated with a conductive material on a polymer ball, and at least one of the first film layer and the second film layer may include a non-conductive film including the elastic protrusions.

### BRIEF DESCRIPTION OF THE DRAWINGS

The above and other aspects, features, and advantages of certain embodiments of the present disclosure will be more apparent from the following description taken in conjunction with the accompanying drawings, in which:

FIGS. 1A to 1C are diagrams illustrating a method of manufacturing a display module to assist understanding of embodiments of the disclosure;

FIG. 2 is a diagram illustrating a structure of a display module according to an embodiment of the disclosure;

FIG. 3 is a diagram illustrating a structure of a display module according to an embodiment of the disclosure;

FIGS. 4 to 8 are diagrams illustrating a method of manufacturing a display module according to an embodiment of the disclosure;

FIGS. 9 to 12 are diagrams illustrating a method of manufacturing a display module according to an embodiment of the disclosure;

FIGS. 13 to 16 are diagrams illustrating various structures of a display module according to embodiments of the disclosure;

FIG. 17 is a flowchart illustrating a method of manufacturing a display module according to an embodiment of the disclosure;

FIG. 18 is a flowchart illustrating a method of manufacturing a display module according to an embodiment of the disclosure.

### DETAILED DESCRIPTION

Embodiments of the present disclosure may be diversely modified. Accordingly, specific non-limiting example embodiments are illustrated in the drawings and are described in detail in the detailed description. However, it is to be understood that the present disclosure is not limited to a specific example embodiment, and includes all modifications, equivalents, and substitutions without departing from the scope and spirit of the present disclosure. Also, well-known functions or constructions may not be described in detail since they may obscure the disclosure with unnecessary detail.

Embodiments of the present disclosure provide a display module with reduced manufacturing cost by simplifying a manufacturing process and a manufacturing method thereof.

General terms that are currently widely used were selected as terms used in describing embodiments of the disclosure in consideration of functions of embodiments in the disclosure, but may be changed depending on the intention of those skilled in the art or a judicial precedent, the emergence of a new technique, and the like. In addition, in a specific case, terms arbitrarily chosen by an applicant may exist. In this example, the meaning of such terms will be mentioned in detail in a corresponding description portion of the disclosure. Therefore, the terms used in describing embodiments of the disclosure should be defined on the basis of the meaning of the terms and the contents throughout the disclosure rather than simple names of the terms.

In this specification, the expressions “have,” “may have,” “include,” or “may include” or the like represent presence of a corresponding feature (e.g., components such as numbers, functions, operations, or parts) and does not exclude the presence of additional features.

The expression “at least one of A and B” should be understood to represent “A” or “B” or both of “A and B”

As used herein, the terms “first,” “second,” or the like may denote various components, regardless of order and/or importance, and may be used to distinguish one component from another, and does not limit the components.

A singular expression includes a plural expression, unless otherwise specified. It is to be understood that the terms such as “comprise” or “include” are used herein to designate a presence of a characteristic, number, step, operation, element, component, or a combination thereof, and not to preclude a presence or a possibility of adding one or more of other characteristics, numbers, steps, operations, elements, components or a combination thereof.

In this disclosure, the term “user” may refer to a person who uses an electronic apparatus or an apparatus (e.g., artificial intelligence electronic apparatus) that uses an electronic apparatus.

Hereinbelow, with reference to the attached drawings, various non-limiting example embodiments of the disclosure will be described in greater detail.

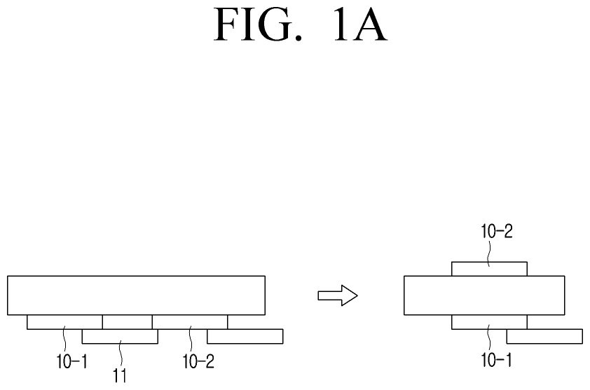

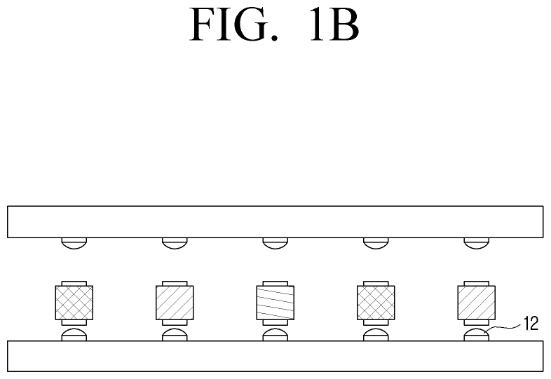

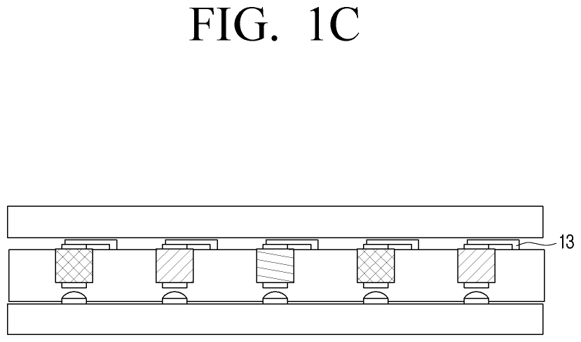

FIGS. 1A to 1C are diagrams illustrating a method of manufacturing a display module to assist understanding of embodiments of the disclosure.

A display module may include an inorganic light emitting device. The inorganic light emitting device may emit light by receiving power through two electrodes. For example, the inorganic light emitting device may include a first terminal 10-1 and a second terminal 10-2 on one side, and the first terminal 10-1 and the second terminal 10-2 may be connected to two terminals of the substrate, respectively. This scheme is referred to as a flip chip scheme.

In the meantime, as a size of the inorganic light emitting device gets smaller, it is difficult to align the first terminal 10-1 and the second terminal 10-2 of the inorganic light emitting device on each of the two terminals of the substrate. For example, as illustrated on the left of FIG. 1A, a problem in which the first terminal 10-1 and the second terminal 10-2 of an inorganic light emitting device are all connected to one terminal of a substrate may occur.

In order to address this problem, as illustrated on the right of FIG. 1A, it is devised that the first terminal 10-1 is formed on one side of an inorganic light emitting device, and the second terminal 10-2 is formed on the other side. Such a scheme is referred to as a vertical chip scheme, and pattern precision and connection precision are improved compared to a flip chip scheme.

However, in the case of a vertical chip type, an exposure and a deposition process are required in a process of forming a bump or forming a pattern and thus, there is a problem of increasing process costs and equipment investment costs. For example, as illustrated in FIG. 1B, a process cost may be increased as an exposure and a deposition process are required in a bump formation process. In addition, the upper and lower electrodes are connected by melting the bump 12 with heat or pressure, but a chip shift/void problem may occur in this process. Alternatively, as illustrated in FIG. 1C, a wiring 13 may be formed through an exposure process and a deposition process, but in this example, there may be a problem in that a process cost may increase.

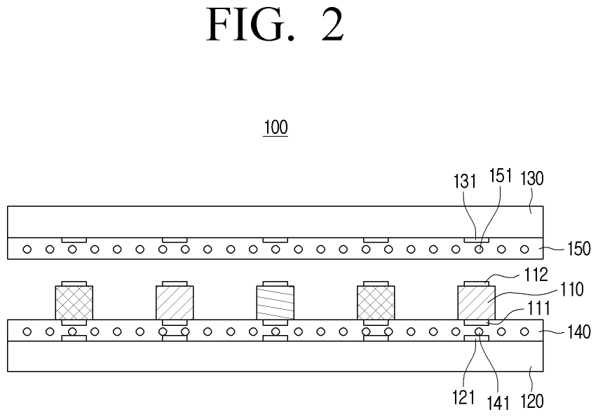

FIG. 2 is a diagram illustrating a structure of a display module 100 according to an embodiment of the disclosure.

As illustrated in FIG. 2, the display module 100 may include an inorganic light emitting device 110, a first substrate 120 including a first electrode 121, a second substrate 130 including a second electrode 131, a first film layer 140 including a plurality of first conductive particles 141, and a second film layer 150 including a plurality of second conductive particles 151. Here, the first substrate 120 may be implemented as a thin-film transistor (TFT), and the second substrate 130 may be implemented as glass. The first film layer 140 may be disposed between the first substrate 120 and the inorganic light emitting device 110 to connect the first electrode 121 to a lower electrode 111 formed on one side of the inorganic light emitting device 110 through at least one of the first conductive particles 141, and the second film layer 150 may be disposed between the second substrate 130 and the inorganic light emitting device 110 to connect the second electrode 131 and an upper electrode 112 formed on the opposite side of the lower electrode 111 in the inorganic light emitting device 110 through at least one of the second conductive particles 151.

For example, at least one from among the plurality of first conductive particles 141 and the plurality of second conductive particles 151 is a fine conductive particle, and at least one from among the first film layer 140 and the second film layer 150 may be formed of an anisotropic conductive film (ACF) including fine conductive particles. Here, the inorganic light emitting device 110 may be provided in plural, as a plurality of inorganic light emitting devices, and a distance between adjacent fine conductive particles among the plurality of fine conductive particles included in the ACF may be smaller than a distance between adjacent inorganic light emitting devices among the plurality of inorganic light emitting devices.

Each of the plurality of fine conductive particles 141 may be smaller than the electrode in terms of the size. Accordingly, it is possible to prevent a short circuit between left and right adjacent electrodes. In addition, heat or pressure may be applied to the film layer to bring the plurality of fine conductive particles into contact with the upper electrode 112 and the lower electrode 111, but the shape of the plurality of fine conductive particles may not be changed. For example, even if heat is applied, the shape of the plurality of fine conductive particles may not be changed.

At least one from among the first substrate 120 and the second substrate 130 may be of a transparent material.

The upper electrode 112, the lower electrode 111, the first electrode 121, and the second electrode 131 may be transparent materials.

As described above, since the inorganic light emitting device 110 and the substrate are bonded using the ACF without an exposure and deposition process, process costs and investment costs may be decreased.

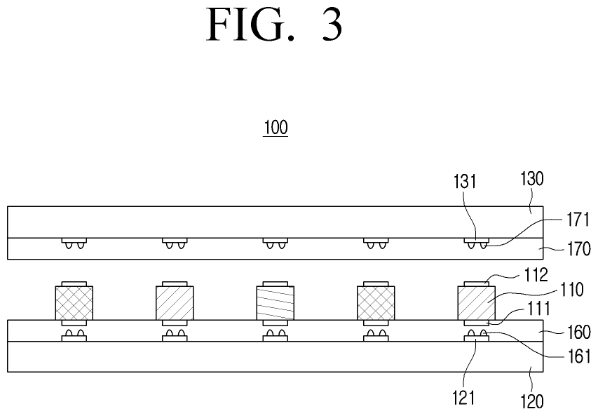

FIG. 3 is a diagram illustrating a structure of the display module 100 according to an embodiment of the disclosure.

As illustrated in FIG. 3, the display module 100 may include the inorganic light emitting device 110, a first substrate 120 including the first electrode 121, the second substrate 130 including the second electrode 131, a first film layer 160 including a plurality of first conductive particles 161, and a second film layer 170 including a plurality of second conductive particles 171. Here, the first film layer 160 is disposed between the first substrate 120 and the inorganic light emitting device 110 to connect the first electrode 121 to the lower electrode 111 formed on one side of the inorganic light emitting device 110 through at least one of the first conductive particles 161, and the second film layer 170 is disposed between the second substrate 130 and the inorganic light emitting device 110 to connect the second electrode 131 and the upper electrode 112 formed on the opposite side of the lower electrode 111 of the inorganic light emitting device 110 through at least one of the second conductive particles 171.

For example, at least one from among the plurality of first conductive particles 161 and the plurality of second conductive particles 171 may be an elastic protrusion coated with a conductive material (Indium tin oxide (ITO)) on a polymer ball, and at least one from among the first film layer 160 and the second film layer 170 may be formed of a non-conductive film (NCF) including the elastic protrusion. Here, the inorganic light emitting device 110 may be provided in plural, as a plurality of inorganic light emitting devices, and a distance between adjacent elastic protrusions among a plurality of elastic protrusions included in the NCF may be less than distance between adjacent inorganic light emitting devices among the plurality of inorganic light emitting devices.

Each of the plurality of elastic protrusions may be smaller than the electrode in size. Accordingly, it is possible to prevent a short circuit between left and right adjacent electrodes. In addition, heat or pressure may be applied to the film layer to bring the plurality of elastic protrusions into contact with the upper electrode 112 and the lower electrode 111, but the shape of the plurality of elastic protrusions may not be changed. For example, even if heat is applied, the shape of the plurality of elastic protrusions may not be changed.

At least one from among the first substrate 120 and the second substrate 130 may be made of a transparent material.

The upper electrode 112, the lower electrode 111, the first electrode 121, and the second electrode 131 may be made of a transparent material.

As described above, since the inorganic light emitting device 110 and the substrate are bonded using the NCF without an exposure and deposition process, process costs and investment costs may be decreased.

In the meantime, in order to assist understanding the structure of the display module 100 in FIGS. 2 and 3, the inorganic light emitting device 110 and the second substrate 130 are illustrated as being spaced apart from each other, but the inorganic light emitting device 110 and the second substrate 130 may be finally bonded.

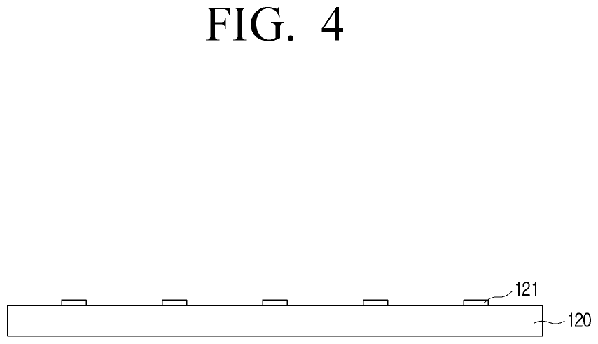

A method of manufacturing the display module 100 will be described in more detail below with reference to FIGS. 4 to 16. In FIGS. 4 to 16, an individual embodiment will be described for convenience of description. However, the individual embodiments of FIGS. 4 to 16 may be performed in a combined state.

FIGS. 4 to 8 are diagrams illustrating a method of manufacturing the display module 100 according to an embodiment of the disclosure. More particularly, FIGS. 4 to 8 are diagrams illustrating a method of manufacturing the display module 100 having the structure of FIG. 3.

First of all, as illustrated in FIG. 4, the first substrate 120 including the first electrode 121 may be formed on an upper portion. Here, the first electrode 121 and the first substrate 120 may be transparent materials.

The first substrate 120 may include a plurality of the first electrode 121. Each first electrode 121 may be connected to a respective one from among a plurality of inorganic light emitting devices.

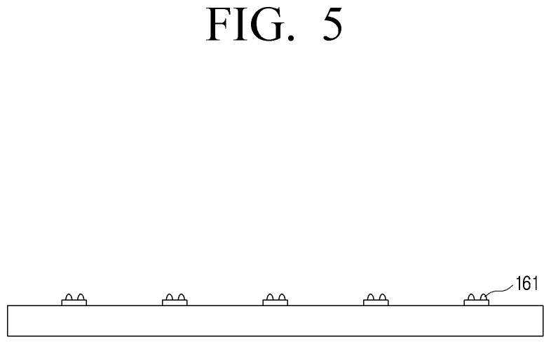

As illustrated in FIG. 5, at least one first conductive particle 161 may be disposed at an upper portion of the first electrode 121. FIG. 5 illustrates that two first conductive particles 161 are disposed on one first electrode 121, but embodiments of the disclosure are not limited thereto. For example, one first conductive particle 161 may be disposed on one first electrode 121, or three or more first conductive particles 161 may be disposed. Here, the plurality of first conductive particles 161 may be an elastic protrusion coated with a conductive material (Indium tin oxide (ITO)) on a polymer ball. However, the embodiment is not limited thereto, and the plurality of first conductive particles 161 may be formed of other materials as long as it is a conductive material. In addition, the plurality of first conductive particles 161 may be a material having a melting point higher than that of a related-art bump. For example, the plurality of first conductive particles 161 may be a material of which the shape is maintained even if heat for melting a non-conductive film (NCF) to be described later is applied.

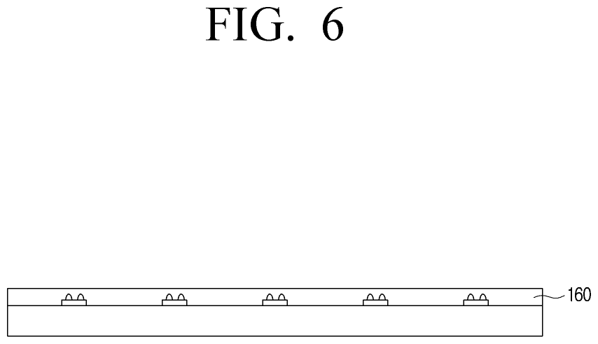

As illustrated in FIG. 6, the first film layer 160 may be bonded to an upper portion of the first substrate 120. For example, the first film layer 160 may be formed of a non-conductive film (NCF). However, the embodiment is not limited thereto, and the first film layer 160 may be formed of a different type of film.

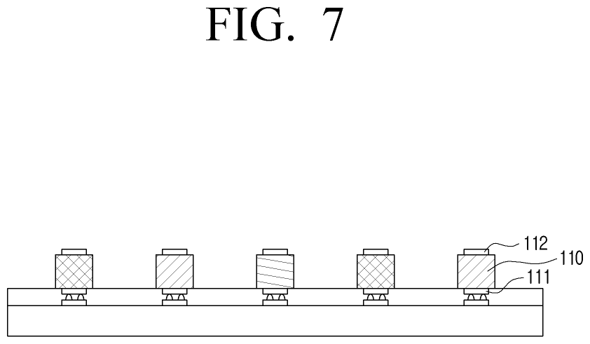

As illustrated in FIG. 7, the inorganic light emitting device 110, including the upper electrode 112 and the lower electrode 111 formed on opposite sides of the inorganic light emitting device 110, may be disposed on the upper portion of the first film layer 160. Thereafter, the first substrate 120 and the inorganic light emitting device 110 are bonded using at least one from among heat and pressure to connect the lower electrode 111 and the first electrode 121 through at least one of the first conductive particles 161. Here, the upper electrode 112 and the lower electrode 111 may be transparent materials.

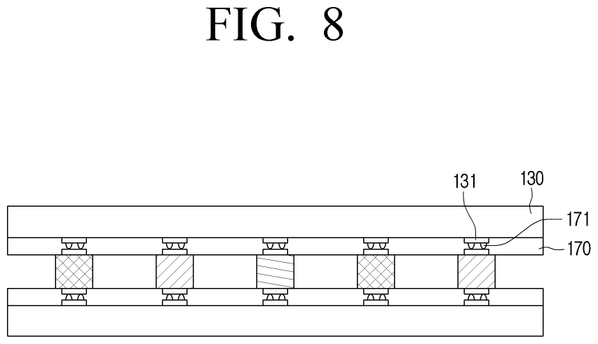

As illustrated in FIG. 8, the second substrate 130 including the second electrode 131 at a lower portion thereof, having at least one of the second conductive particles 171 disposed under the second electrode 131, and having the second film layer 170 bonded to a lower portion of the second substrate 130 may be disposed on an upper portion of the inorganic light emitting device 110. Thereafter, the second substrate 130 and the inorganic light emitting device 110 are bonded using at least one from among heat and pressure to connect the upper electrode 112 and the second electrode 131 through at least one of the second conductive particles 171.

The disposing at an upper portion of the inorganic light emitting device 110 may include forming the second substrate 130 including the second electrode 131 on the lower portion thereof, disposing at least one of the second conductive particles 171 on the lower portion of the second electrode 131, bonding the second film layer 170 to the lower portion of the second substrate 130, and disposing the second substrate 130 on the upper portion of the inorganic light emitting device 110. That is, the operation of forming the second conductive particles 171 and the second film layer 170 on the second substrate 130 may be the same as the forming the first conductive particle 161 and the first film layer 160 on the first substrate 120.

Here, the plurality of second conductive particles 171 may be an elastic protrusion coated with a conductive material (Indium tin oxide (ITO)) on a polymer ball. However, the embodiment is not limited thereto, and the plurality of second conductive particles 171 may be formed of other materials as long as it is a conductive material. In addition, the plurality of second conductive particles 171 may be a material having a melting point higher than that of a related-art bump. For example, the plurality of second conductive particles171 may be a material of which the shape is maintained even if heat for melting the NCF is applied. The second film layer 170 may be formed of NCF. However, the embodiment is not limited thereto, and the second film layer 170 may be formed of a different type of film. The second electrode 131 and the second substrate 130 may be transparent materials.

According to embodiments, the inorganic light emitting device 110 may be provided in plural, as a plurality of inorganic light emitting devices, and a distance between adjacent elastic protrusions among a plurality of elastic protrusions included in the NCF may be less than distance between adjacent inorganic light emitting devices among the plurality of inorganic light emitting devices.

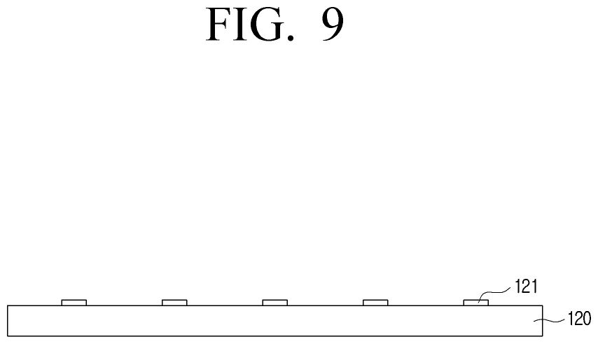

FIGS. 9 to 12 are diagrams illustrating a method of manufacturing the display module 100 according to an embodiment of the disclosure. More particularly, FIGS. 9 to 12 are diagrams illustrating a method of manufacturing the display module 100 having the structure of FIG. 2.

First, as illustrated in FIG. 9, the first substrate 120 including the first electrode 121 may be formed on an upper portion thereof. Here, the first electrode 121 and the first substrate 120 may be transparent materials.

The first substrate 120 may include a plurality of first electrodes 121. Each of the plurality of first electrodes 121 may be connected to a respective one from among a plurality of inorganic light emitting devices 110.

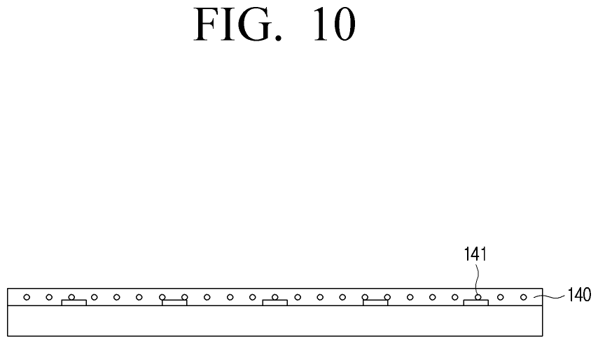

As illustrated in FIG. 10, the first film layer 140 including a plurality of first conductive particles 141 may be bonded to an upper portion of the first substrate 120. Here, the plurality of first conductive particles 141 may be fine conductive particles. However, the embodiment is not limited thereto, and the plurality of first conductive particles 141 may be formed of other materials as long as it is a conductive material. In addition, the plurality of first conductive particles 141 may be a material having a melting point higher than that of a related-art bump. For example, the plurality of first conductive particles 141 may be a material of which the shape is maintained even if heat for melting the ACF to be described later is applied. The first film layer 140 may be formed of the ACF including fine conductive particles. However, the embodiment is not limited thereto, and the first film layer 140 may be formed of a different type of film.

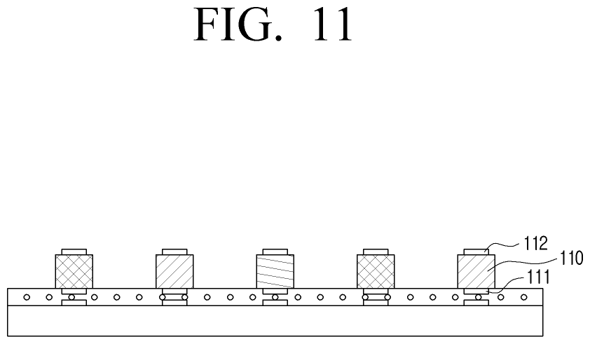

As illustrated in FIG. 11, the inorganic light emitting device 110, including the upper electrode 112 and the lower electrode 111 formed on opposite sides of the light emitting device 110, may be disposed at an upper portion of the first film layer 140. Thereafter, the lower electrode 111 and the first electrode 121 may be connected through at least one of the first conductive particles 141 by bonding the first substrate 120 and the inorganic light emitting device 110 using at least one from among heat and pressure. Here, the upper electrode 112 and the lower electrode 111 may be transparent materials.

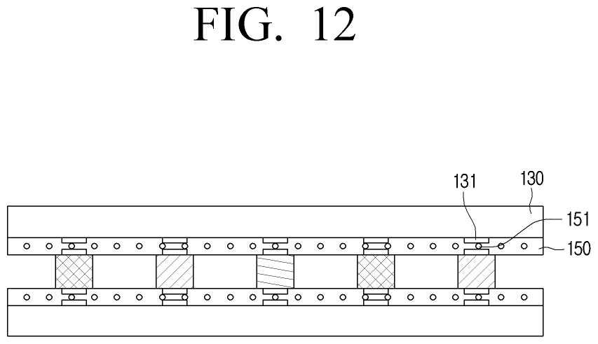

As illustrated in FIG. 12, the second substrate 130, including the second electrode 131 at a lower portion thereof and the second film layer 150 including a plurality of second conductive particles 151 bonded on an upper portion, may be disposed on an upper portion of the inorganic light emitting device 110. Then, the second substrate 130 and the inorganic light emitting device 110 are bonded using at least one from among heat and pressure to connect the upper electrode 112 and the second electrode 131 through at least one of the second conductive particles 151.

Here, the disposing the second substrate 130 on an upper portion of the inorganic light emitting device 110 may include forming the second substrate 130 including the second electrode 131 on a lower portion, bonding the second film layer 150 including a plurality of second conductive particles 151 to a lower portion of the second substrate 130, and disposing the second substrate 130 on an upper portion of the inorganic light emitting device 110. That is, the operation of forming the second conductive particles 151 and the second film layer 150 on the second substrate 130 may be the same as the operation of forming the first conductive particles 141 and the first film layer 140 on the first substrate 120.

Here, the plurality of second conductive particles 151 may be fine conductive particles. However, the embodiment is not limited thereto, and the plurality of second conductive particles 151 may be formed of other materials as long as it is a conductive material. In addition, the plurality of second conductive particles 151 may be a material having a melting point higher than that of a related-art bump. For example, the plurality of second conductive particles 151 may be a material of which the shape is maintained even if heat for melting the ACF is applied. The second film layer 150 may be formed of an ACF including fine conductive particles. However, the embodiment is not limited thereto, and the second film layer 150 may be formed of a different type of film. The second electrode 131 and the second substrate 130 may be transparent materials.

The inorganic light emitting device 110 may be provided in plural, as a plurality of inorganic light emitting devices, and a distance between adjacent fine conductive particles among a plurality of fine conductive particles included in the anisotropic conductive film may be less than distance between adjacent inorganic light emitting devices among the plurality of inorganic light emitting devices.

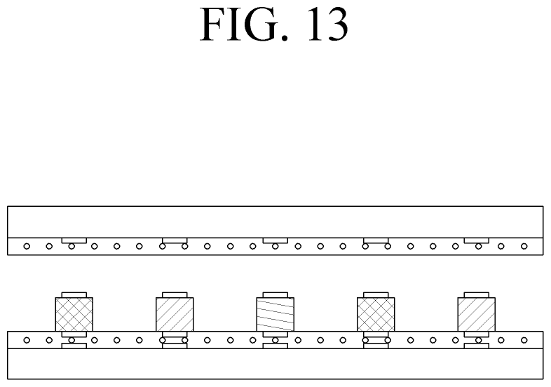

FIGS. 13 to 16 are diagrams illustrating various structures of the display module 100 according to embodiment of the disclosure.

First, the display module 100 may include the first substrate 120 and the second substrate 130 to which the ACF is attached. The structure of FIG. 13 is the same as the structure of FIG. 2 and a duplicate description will be omitted.

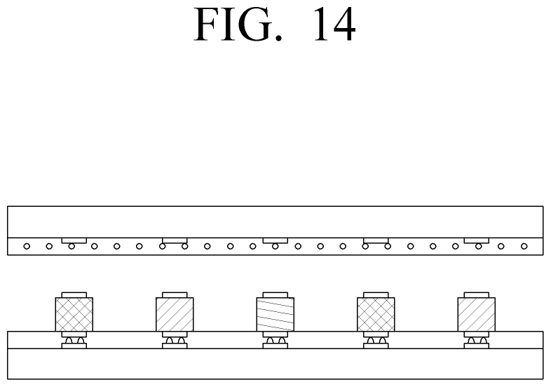

Alternatively, as illustrated in FIG. 14, the display module 100 may include the first substrate 120 to which an NCF is attached and the second substrate 130 to which an ACF is attached. In this example, the first substrate 120 may be manufactured through the method as illustrated in FIGS. 4, 5, and 6, and the second substrate 130 may be manufactured through the method as illustrated in FIGS. 9 and 10.

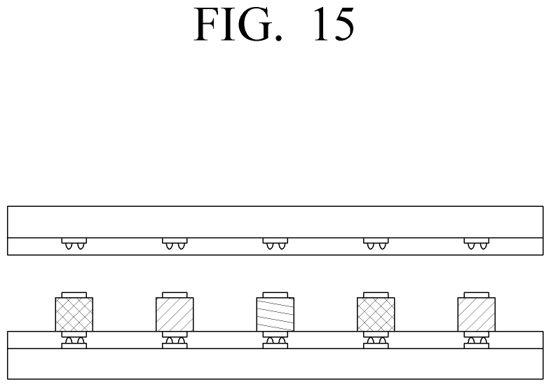

Alternatively, the display module 100 may, as illustrated in FIG. 15, include the first substrate 120 and the second substrate 130 to which the NCF is attached. Since the structure of FIG. 15 is the same as the structure of FIG. 3, a duplicate description will be omitted.

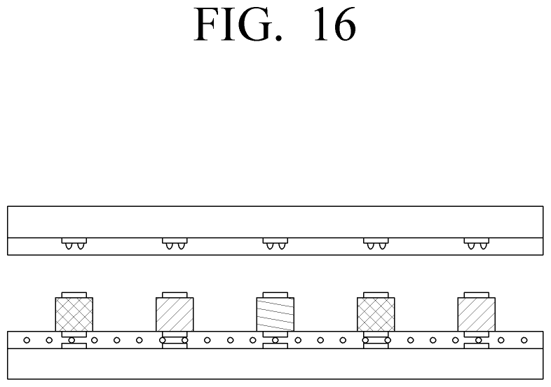

Alternatively, as illustrated in FIG. 16, the display module 100 may include the first substrate 120 to which an ACF is attached and the second substrate 130 to which the NCF is attached. In this example, the first substrate 120 may be manufactured through the method as illustrated in FIGS. 9 and 10, and the second substrate 130 may be manufactured through the method as illustrated in FIGS. 4, 5, and 6.

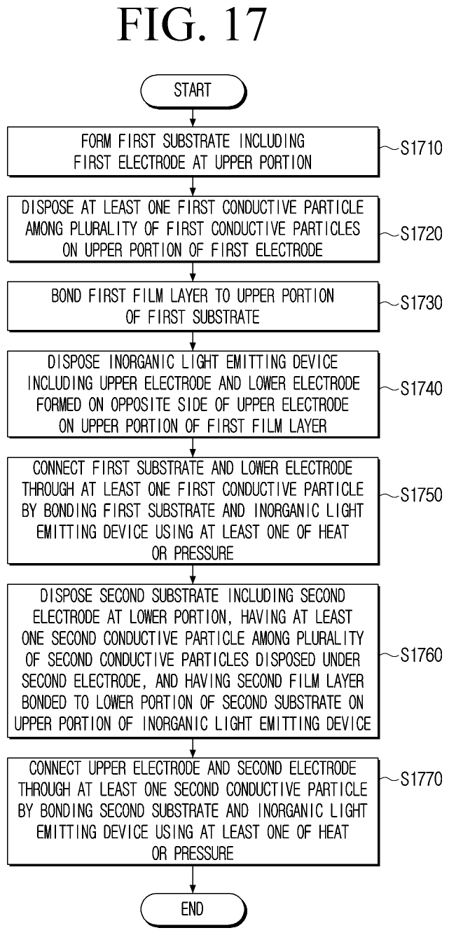

FIG. 17 is a flowchart illustrating a method of manufacturing the display module according to an embodiment of the disclosure.

First, the first substrate including a first electrode is formed on an upper portion of the first substrate in operation S1710. At least one first conductive particle among a plurality of first conductive particles is disposed at an upper portion of the first electrode in operation S1720. The first film layer is bonded to the upper portion of the first substrate in operation S1730. The inorganic light emitting device including an upper electrode and a lower electrode formed on the opposite side of the upper electrode is disposed on the first film layer in operation S1740. The first substrate and the inorganic light emitting device are bonded using at least one from among heat and pressure to connect the lower electrode and the first electrode through at least one first conductive particle in operation S1750. The second substrate, including a second electrode at a lower portion of the second substrate, having a second film layer including a plurality of second conductive particles bonded at a lower portion is disposed on an upper portion of the inorganic light emitting device in operation S1760. The second substrate and the inorganic light emitting element are bonded using at least one from among heat and pressure to connect the upper electrode and the second electrode through at least one second conductive particle in operation S1770.

The disposing at an upper portion of the inorganic light emitting device in operation S1760 may include forming a second substrate comprising a second electrode at a lower portion of the second substrate; bonding the second film layer including the plurality of second conductive particles at the lower portion of the second substrate; and disposing the second substrate at an upper portion of the inorganic light emitting device.

The plurality of first conductive particles and the plurality of second conductive particles may be elastic protrusions coated with a conductive material (Indium tin oxide (ITO)) on a polymer ball, and the first film layer and the second film layer may be formed of a non-conductive film (NCF).

The inorganic light emitting device may be provided in plural, as a plurality of inorganic light emitting devices, and a distance between adjacent elastic protrusions among a plurality of elastic protrusions included in the NCF may be less than distance between adjacent inorganic light emitting devices among the plurality of inorganic light emitting devices.

At least one from among the first substrate and the second substrate may be made of a transparent material.

The upper electrode, the lower electrode, the first electrode, and the second electrode may be made of a transparent material.

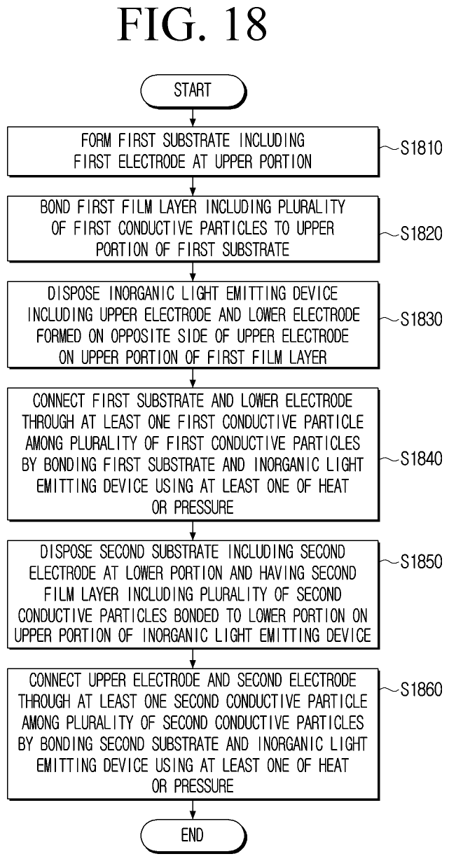

FIG. 18 is a flowchart illustrating a method of manufacturing the display module according to an embodiment of the disclosure.

First, the first substrate including a first electrode is formed on an upper portion of the first substrate in operation S1810. In addition, the first film layer including a plurality of first conductive particles is bonded to the upper portion of the first substrate in operation S1820. The inorganic light emitting device including an upper electrode and a lower electrode formed on an opposite side of the upper electrode is disposed on an upper portion of the first film layer in operation S1830. The first substrate and the inorganic light emitting device are bonded using at least one from among heat and pressure to connect the lower electrode and the first electrode through at least one first conductive particle among the plurality of first conductive particles in operation S1840. The second substrate, including a second electrode at a lower portion of the second substrate and including a plurality of second conductive particles, is disposed at an upper portion of the inorganic light emitting device in operation S1850. The second substrate and the inorganic light emitting device are bonded using at least one from among heat and pressure to connect the upper electrode and the second electrode through at least one second conductive particle among the plurality of second conductive particles in operation S1860.

The disposing at an upper portion of the inorganic light emitting device in operation S1850 may include forming a second substrate comprising a second electrode at a lower portion of the second substrate; bonding the second film layer including the plurality of second conductive particles at the lower portion of the second substrate; and disposing the second substrate at an upper portion of the inorganic light emitting device.

The plurality of first conductive particles and the plurality of second conductive particles may be fine conductive particles, and the first film layer and the second film layer may be formed of an anisotropic conductive film (ACF) comprising the fine conductive particles.

The inorganic light emitting device may be provided in plural, as a plurality of inorganic light emitting devices, and a distance between adjacent fine conductive particles among a plurality of fine conductive particles included in the anisotropic conductive film may be less than distance between adjacent inorganic light emitting devices among the plurality of inorganic light emitting devices.

In addition, at least one from among the first substrate and the second substrate may be a transparent material.

In addition, the upper electrode, the lower electrode, the first electrode, and the second electrode may be transparent materials.

According to various embodiments of the disclosure as described above, since the inorganic light emitting device and the substrate are bonded using the ACF or the NCF without an exposure and deposition process, process costs and investment costs may be reduced.

Various embodiments of the disclosure may be implemented in software, including instructions stored on machine-readable storage media readable by a machine (e.g., a computer). An apparatus may call instructions from the storage medium, and execute the called instruction, including an electronic apparatus (for example, electronic apparatus A) according to the disclosed embodiments. When the instructions are executed by a processor, the processor may perform a function corresponding to the instructions directly or using other components under the control of the processor. The instructions may include a code generated by a compiler or a code executable by an interpreter. A machine-readable storage medium may be provided in the form of a non-transitory storage medium. Herein, the “non-transitory” storage medium may not include a signal but is tangible, and does not distinguish the case in which a data is semi-permanently stored in a storage medium from the case in which a data is temporarily stored in a storage medium.

According to one or more embodiments, the method according to the above-described embodiments may be included in a computer program product. The computer program product may be traded as a product between a seller and a consumer. The computer program product may be distributed online in the form of machine-readable storage media (e.g., compact disc read only memory (CD-ROM)) or through an application store (e.g., Play Store™) or distributed online directly. In the case of online distribution, at least a portion of the computer program product may be at least temporarily stored or temporarily generated in a server of the manufacturer, a server of the application store, or a machine-readable storage medium such as memory of a relay server.

The above-described various embodiments may be implemented in a computer- or similar device-readable recording medium using software, hardware, or a combination thereof. In some embodiments, one or more embodiments described herein may be implemented with the processor itself. Through the software implementation, elements such as a procedure and function described herein may be implemented with separate software modules. The software modules may perform one or more functions and operations described herein.

Computer instructions for performing a processing operation of the apparatuses according to the above-described various embodiments may be stored in a non-transitory computer-readable medium. The computer instructions stored in the non-transitory computer-readable medium may allow a specific apparatus to perform the processing operation in the apparatus according to the above-described embodiments when the computer instructions are executed through a processor of the specific apparatus. The non-transitory computer-recordable medium is not a medium configured to temporarily store data such as a register, a cache, or a memory but an apparatus-readable medium configured to semi-permanently store data. Specifically, the non-transitory apparatus-readable medium may be a compact disc (CD), a digital versatile disc (DVD), a hard disc, a Blu-ray disc, a universal serial bus (USB), a memory card, a read only memory (ROM), and the like.

According to various embodiments, the respective elements (e.g., module or program) of the elements mentioned above may include a single entity or a plurality of entities. According to the embodiments, at least one element or operation from among the corresponding elements mentioned above may be omitted, or at least one other element or operation may be added. Alternatively or additionally, a plurality of components (e.g., module or program) may be combined to form a single entity. In this case, the integrated entity may perform functions of at least one function of an element of each of the plurality of elements in the same manner as or in a similar manner to that performed by the corresponding element from among the plurality of elements before integration. The module, a program module, or operations executed by other elements according to variety of embodiments may be executed consecutively, in parallel, repeatedly, or heuristically, or at least some operations may be executed according to a different order, may be omitted, or the other operation may be added thereto.

While example embodiments have been illustrated and described, the disclosure is not limited to the specific example embodiments, and it is to be understood that the disclosure is not limited to the specific example embodiments as described above, it will be understood by those of ordinary skill in the art that various changes in form and details may be made therein without departing from the spirit and scope as defined by the following claims and their equivalents.

What is claimed is:

1. A display module comprising:
an inorganic light emitting device comprising a lower electrode on a first side of the inorganic light emitting device and an upper electrode on a second side of the inorganic light emitting device, opposite to the first side;
a first substrate at the first side of the inorganic light emitting device and comprising a first electrode;
a second substrate at the second side of the inorganic light emitting device and comprising a second electrode;
a first film layer between the first substrate and the inorganic light emitting device and comprising a plurality of first conductive particles; and
a second film layer between the second substrate and the inorganic light emitting device and comprising a plurality of second conductive particles,
wherein the first film layer is configured to connect the first electrode and the lower electrode through at least one of the plurality of first conductive particles, and
wherein the second film layer is configured to connect the second electrode and the upper electrode through at least one of the plurality of second conductive particles.

2. The display module of claim 1, wherein at least one of the plurality of first conductive particles and the plurality of second conductive particles are fine conductive particles, and
wherein at least one of the first film layer and the second film layer comprises an anisotropic conductive film comprising the fine conductive particles.

3. The display module of claim 2, further comprising an additional inorganic light emitting device that is adjacent to the inorganic light emitting device, and
wherein a distance between adjacent fine conductive particles among the fine conductive particles in the anisotropic conductive film is less than a distance between the inorganic light emitting device and the additional inorganic light emitting device.

4. The display module of claim 1, wherein at least one of the plurality of first conductive particles and the plurality of second conductive particles comprises elastic protrusions coated with a conductive material on a polymer ball, and
wherein at least one of the first film layer and the second film layer comprises a non-conductive film comprising the elastic protrusions.

5. The display module of claim 4, further comprising an additional inorganic light emitting device that is adjacent to the inorganic light emitting device, and
wherein a distance between adjacent elastic protrusions among the elastic protrusions in the non-conductive film is less than a distance between the inorganic light emitting device and the additional inorganic light emitting device.

6. The display module of claim 1, wherein at least one of the first substrate and the second substrate comprises a transparent material.

7. The display module of claim 1, wherein each of the upper electrode, the lower electrode, the first electrode, and the second electrode comprises a transparent material.

8. A method of manufacturing a display module, the method comprising:
forming a first substrate comprising a first electrode at an upper portion of the first substrate;
disposing at least one first conductive particle on an upper portion of the first electrode;
bonding a first film layer to the upper portion of the first substrate;
disposing an inorganic light emitting device on an upper portion of the first film layer, the inorganic light emitting device comprising an upper electrode and a lower electrode formed on opposite sides of the inorganic light emitting device;
connecting the first substrate and the lower electrode through the at least one first conductive particle by bonding the first substrate and the inorganic light emitting device using at least one of heat and pressure;
disposing a second substrate and a second film layer, bonded to a lower portion of the second substrate, on an upper portion of the inorganic light emitting device, the second substrate comprising a second electrode at the lower portion of the second substrate, and the second film layer including at least one second conductive particle under the second electrode; and
connecting the upper electrode and the second electrode through the at least one second conductive particle by bonding the second substrate and the inorganic light emitting device using at least one of heat and pressure.

9. The method of claim 8, wherein the disposing the second substrate and the second film layer comprises:
forming the second substrate;
disposing the at least one second conductive particle at a lower portion of the second electrode;
bonding the second film layer to the lower portion of the second substrate; and
disposing the second substrate at the upper portion of the inorganic light emitting device.

10. The method of claim 8, wherein the at least one first conductive particle and the at least one second conductive particle are elastic protrusions coated with a conductive material on a polymer ball, and
wherein the first film layer and the second film layer include a non-conductive film.

11. The method of claim 10, further comprising disposing an additional inorganic light emitting device on the upper portion of the first film layer such as to be adjacent to the inorganic light emitting device,
wherein a distance between adjacent elastic protrusions among the elastic protrusions in the non-conductive film is less than distance between the inorganic light emitting device and the additional inorganic light emitting device.

12. The method of claim 8, wherein at least one of the first substrate and the second substrate comprises a transparent material.

13. The method of claim 8, wherein each of the upper electrode, the lower electrode, the first electrode, and the second electrode comprises a transparent material.

14. A display module comprising:
an inorganic light emitting device;
a first electrode at a first side of the inorganic light emitting device;
a second electrode at a second side of the inorganic light emitting device, opposite to the first side;
a first film layer between the first electrode and the inorganic light emitting device and comprising a plurality of first conductive particles; and
a second film layer being between the second electrode and the inorganic light emitting device and comprising a plurality of second conductive particles,
wherein the first film layer is configured to connect the first electrode and the inorganic light emitting device through at least one of the plurality of first conductive particles, and
wherein the second film layer is configured to connect the second electrode and the inorganic light emitting device through at least one of the plurality of second conductive particles.

15. The display module of claim 14, wherein at least one of the plurality of first conductive particles and the plurality of second conductive particles are fine conductive particles, and
wherein at least one of the first film layer and the second film layer comprises an anisotropic conductive film comprising the fine conductive particles.

16. The display module of claim 14, wherein at least one of the plurality of first conductive particles and the plurality of second conductive particles comprises elastic protrusions coated with a conductive material on a polymer ball, and
wherein at least one of the first film layer and the second film layer comprises a non-conductive film comprising the clastic protrusions.
